(19) United States
(12) Patent Application Publication
(10) Pub. No.: US 2025/0290867 A1
(43) Pub. Date: Sep. 18, 2025

(54) SEMICONDUCTOR INSPECTION APPARATUS AND METHOD OF MANUFACTURING SEMICONDUCTOR DEVICE

(71) Applicant: Mitsubishi Electric Corporation, Tokyo (JP)

(72) Inventors: Akifumi IMAI, Tokyo (JP); Takanori TANAKA, Tokyo (JP); Hiroyuki AMISHIRO, Tokyo (JP); Kazuya ISHIBASHI, Tokyo (JP)

(73) Assignee: Mitsubishi Electric Corporation, Tokyo (JP)

(21) Appl. No.: 18/976,233

(22) Filed: Dec. 10, 2024

(30) Foreign Application Priority Data
Mar. 18, 2024 (JP) 2024-042109

(51) Int. Cl. G01N 21/95; G01N 21/64; G01N 21/88; H01L 21/265; H01L 21/324; H01L 21/66

(52) U.S. Cl. CPC G01N 21/9501; G01N 21/6489; G01N 21/8851; H01L 22/12; G01N 2021/8861; G01N 2021/8887; H01L 21/265; H01L 21/324

(57) ABSTRACT

A semiconductor inspection apparatus includes first inspection information acquisition circuitry, second inspection information acquisition circuitry, and screening circuitry. The first inspection information acquisition circuitry acquires first image information including unevenness information on the surface of a semiconductor wafer before ion implantation. The second inspection information acquisition circuitry acquires second image information including information on photoluminescence in the semiconductor wafer subjected to heat treatment after the ion implantation. The screening circuitry specifies a defect included in the semiconductor wafer on the basis of the first image information and the second image information, and determines the quality of a semiconductor chip formed on the semiconductor wafer.

### BACKGROUND OF THE INVENTION

### Field of the Invention

The present disclosure relates to a semiconductor inspection apparatus and a method of manufacturing a semiconductor device.

### Description of the Background Art

Crystal defects lead to deterioration of reliability of a semiconductor element. Therefore, when a specific crystal defect occurs in a semiconductor wafer, a screening technique for selectively removing a semiconductor chip including the crystal defect is required. Crystal defects of a semiconductor are detected by, for example, a method of acquiring a surface shape of a semiconductor wafer or a method of measuring photoluminescence, as described in Japanese Patent No. 5713419 and Japanese Patent Application Laid-Open No. 2022-163866.

A defect is expanded or contracted by a heat treatment process included in the wafer process. In a case where the defect inspection is performed before the entire heat treatment process is completed, the inspection result does not reflect the influence of expansion or contraction of the defect. On the other hand, when the defect inspection is performed after the thermal process is completed, the contrast caused by the chip pattern formed on the semiconductor wafer is superimposed on the inspection result. Therefore, the classification accuracy of the defect type decreases.

### SUMMARY

An object of the present disclosure is to provide a semiconductor inspection apparatus capable of improving classification accuracy in defect inspection and determining quality of a semiconductor device with high accuracy.

A semiconductor inspection apparatus according to the present disclosure includes a first inspection information acquisition unit, a second inspection information acquisition unit, and a screening unit. The first inspection information acquisition unit acquires first image information. The first image information includes unevenness information on the surface of a semiconductor wafer before ion implantation. The second inspection information acquisition unit acquires second image information. The second image information includes information on photoluminescence in the semiconductor wafer subjected to heat treatment after the ion implantation. The screening unit specifies a defect included in the semiconductor wafer on the basis of the first image information and the second image information, and determines the quality of a semiconductor chip formed on the semiconductor wafer.

A semiconductor inspection apparatus that improves classification accuracy in defect inspection and determines quality of a semiconductor device with high accuracy is provided.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a semiconductor inspection apparatus according to a first preferred embodiment;

FIG. 2 is a diagram illustrating an example of a configuration of a processing circuit included in the semiconductor inspection apparatus;

FIG. 3 is a diagram illustrating another example of a configuration of a processing circuit included in the semiconductor inspection apparatus;

FIG. 4 is a flowchart illustrating a method of manufacturing a semiconductor device according to the first preferred embodiment;

FIG. 5 is a flowchart illustrating details of a screening process;

FIG. 6 is a diagram illustrating a configuration of a semiconductor chip and a defect inspection region;

FIG. 7 is a diagram illustrating a configuration of a semiconductor chip and a defect inspection region;

FIG. 8 is a diagram illustrating a configuration of a semiconductor inspection apparatus according to a second preferred embodiment;

FIG. 9 is a diagram illustrating data processing in the semiconductor inspection apparatus;

FIG. 10 is a diagram illustrating a configuration of a semiconductor inspection apparatus according to a modification of the second preferred embodiment;

FIG. 11 is a diagram illustrating data processing in the semiconductor inspection apparatus;

FIG. 12 is a diagram illustrating a configuration of a semiconductor inspection apparatus according to a third preferred embodiment; and

FIG. 13 is a diagram illustrating data processing in the semiconductor inspection apparatus.

### DESCRIPTION OF THE PREFERRED EMBODIMENTS

### First Preferred Embodiment

A semiconductor inspection apparatus according to the present disclosure inspects a semiconductor wafer in a manufacturing process of a semiconductor device. A plurality of semiconductor chips are formed on a semiconductor wafer. A semiconductor chip is, for example, a power semiconductor chip formed of Si or SiC.

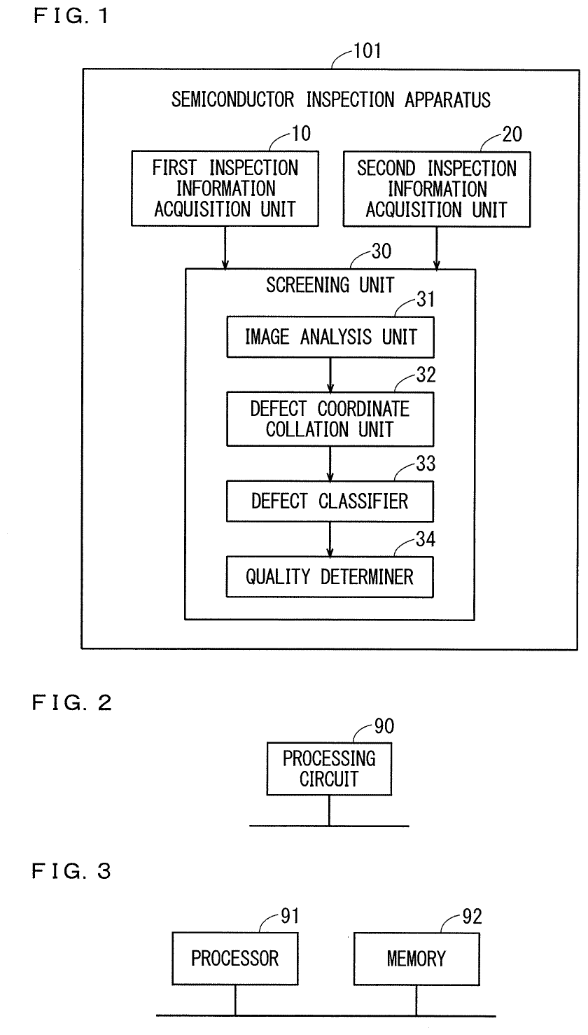

FIG. 1 is a diagram illustrating a configuration of a semiconductor inspection apparatus 101 according to a first preferred embodiment. The semiconductor inspection apparatus 101 includes a first inspection information acquisition unit 10, a second inspection information acquisition unit 20, and a screening unit 30.

The first inspection information acquisition unit 10 acquires first image information. The first image information includes unevenness information on the surface of a semiconductor wafer before ion implantation. The first image information is, for example, a surface image of a semiconductor wafer acquired by the differential interference optical system.

The second inspection information acquisition unit 20 acquires second image information. The second image information includes information on photoluminescence (PL) in the semiconductor wafer subjected to heat treatment after the ion implantation. The heat treatment temperature is preferably 1000° C. or higher. The second image information is, for example, a photoluminescence image (PL image) acquired by the PL method.

The screening unit 30 specifies a defect included in the semiconductor wafer on the basis of the first image information and the second image information, and determines the quality of a semiconductor chip formed on the semiconductor wafer. The screening unit 30 includes an image analysis unit 31, a defect coordinate collation unit 32, a defect classifier 33, and a quality determiner 34.

The image analysis unit 31 performs subtraction of the contrast related to the ion implantation pattern of the semiconductor wafer in the second image information.

The defect coordinate collation unit 32 specifies the position of the defect included in the semiconductor wafer based on the first image information and the second image information.

The defect classifier 33 identifies the type of the defect based on the first image information and the second image information subjected to the subtraction of the contrast.

The quality determiner 34 determines the quality of the semiconductor chip based on the type of the defect.

FIG. 2 is a diagram illustrating an example of a configuration of a processing circuit 90 included in the semiconductor inspection apparatus 101. The functions of the first inspection information acquisition unit 10, the second inspection information acquisition unit 20, and the screening unit 30 are implemented by the processing circuit 90. In other words, the processing circuit 90 includes the first inspection information acquisition unit 10, the second inspection information acquisition unit 20, and the screening unit 30.

In a case where the processing circuit 90 is dedicated hardware, the processing circuit 90 is, for example, a single circuit, a composite circuit, a programmed processor, a parallel programmed processor, an application specific integrated circuit (ASIC), a field-programmable gate array (FPGA), a circuit obtained by combining these, or the like. The functions of the first inspection information acquisition unit 10, the second inspection information acquisition unit 20, and the screening unit 30 may be implemented by a plurality of processing circuits, or may be implemented collectively by one processing circuit.

FIG. 3 is a diagram illustrating another example of a configuration of a processing circuit included in the semiconductor inspection apparatus 101. The processing circuit includes a processor 91 and a memory 92. The processor 91 executes the program stored in the memory 92, thereby implementing the functions of the first inspection information acquisition unit 10, the second inspection information acquisition unit 20, and the screening unit 30. For example, software described as a program is executed by the processor 91 to implement each function. As described above, the semiconductor inspection apparatus 101 includes the memory 92 that stores the program and the processor 91 that executes the program.

The program describes a function in which the semiconductor inspection apparatus 101 acquires first image information including irregularity information on a surface of a semiconductor wafer before ion implantation, acquires second image information including information on photoluminescence in the semiconductor wafer subjected to heat treatment after ion implantation, extracts defects included in the semiconductor wafer on the basis of the first image information and the second image information, and determines the quality of a semiconductor chip formed on the semiconductor wafer. The program causes a computer to execute procedures or methods of the first inspection information acquisition unit 10, the second inspection information acquisition unit 20, and the screening unit 30.

The processor 91 is, for example, a central processing unit (CPU) or the like. The memory 92 is, for example, a nonvolatile or volatile semiconductor memory such as a random access memory (RAM), a read only memory (ROM), a flash memory, an erasable programmable read only memory (EPROM), or an electrically erasable programmable read only memory (EEPROM). Alternatively, the memory 92 may be a hard disk drive (HDD) or the like.

A part of the functions of the first inspection information acquisition unit 10, the second inspection information acquisition unit 20, and the screening unit 30 may be realized by dedicated hardware, and another part may be realized by software. The processing circuit implements the above functions by a combination of hardware and software.

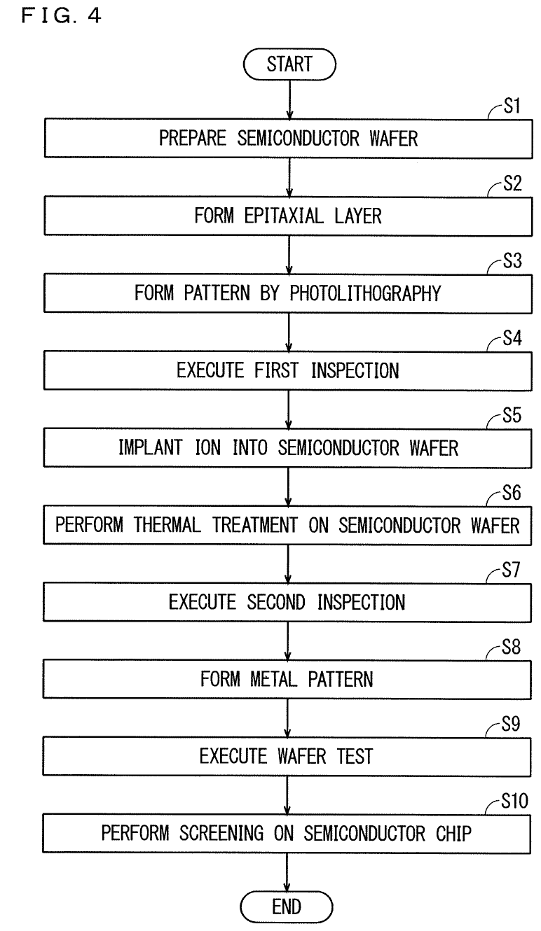

FIG. 4 is a flowchart illustrating a method of manufacturing a semiconductor device according to the first preferred embodiment. The defect inspection method by the semiconductor inspection apparatus 101 is applied to this manufacturing method.

In step S1, a semiconductor wafer is prepared. In step S2, a semiconductor layer is formed on the upper surface of the semiconductor wafer by an epitaxial growth method. Hereinafter, this semiconductor layer is referred to as an epitaxial layer. In step S3, a predetermined pattern is formed on the surface of the semiconductor wafer by photolithography.

In step S4, first inspection is executed. First inspection is an inspection by the differential interference optical system, and is executed after the epitaxial growth process (step S2) and before the ion implantation process (step S5). In the first inspection process, the semiconductor inspection apparatus 101 photographs a surface image of the semiconductor wafer.

In step S5, ions are implanted into the surface of the semiconductor wafer.

In step S6, the semiconductor wafer is heat-treated at a temperature of 1000° C. or higher. Ions injected into the semiconductor wafer are activated by the heat treatment.

In step S7, second inspection is executed. Second inspection is an inspection by the PL method, and is executed after the heat treatment process (step S6) and before the metal forming process (step S8). In the second inspection process, the semiconductor inspection apparatus 101 measures the PL image on the semiconductor wafer.

In step S8, a metal pattern is formed on the surface of the semiconductor wafer.

In step S9, a wafer test is executed. In the wafer test, the electrical static characteristics of the semiconductor chip are inspected. A semiconductor chip whose result of the wafer test is out of specification is removed and discarded.

In step S10, the screening unit 30 specifies a defect included in the semiconductor wafer on the basis of the surface image and the PL image, and determines the quality of the semiconductor chip. The screening unit 30 removes a defective semiconductor chip on the basis of the quality information. That is, the screening unit 30 screens the semiconductor chip. As a result, a defective semiconductor chip falls off. Thereafter, a semiconductor device is completed through a mounting process such as wiring of the semiconductor chip.

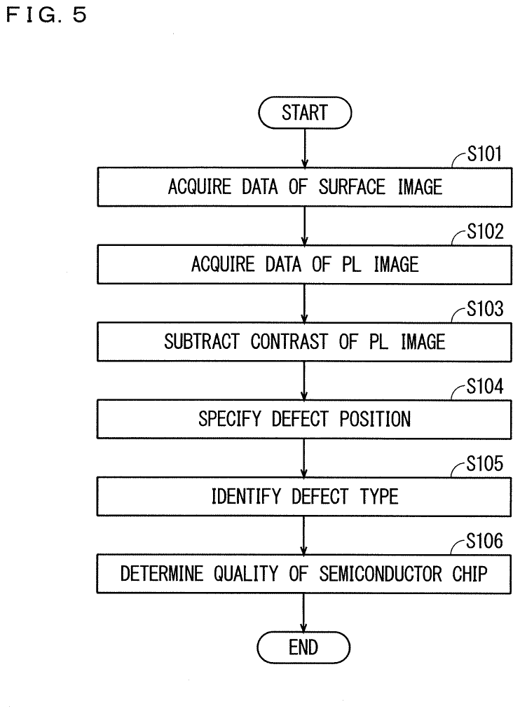

FIG. 5 is a flowchart illustrating details of the screening process in step S10.

In step S101, the first inspection information acquisition unit 10 acquires data of the surface image of the semiconductor wafer as the first image information.

In step S102, the second inspection information acquisition unit 20 acquires data of the PL image on the semiconductor wafer as the second image information.

In step S103, the image analysis unit 31 performs subtraction of the contrast related to the ion implantation pattern in the PL image.

In step S104, the defect coordinate collation unit 32 specifies the position of the defect based on the surface image and the PL image subjected to subtraction of the contrast.

In step S105, the defect classifier 33 identifies the type of the defect based on the surface image and the PL image subjected to subtraction of the contrast.

In step S106, the quality determiner 34 determines the quality of the semiconductor chip formed on the semiconductor wafer based on the information on the type of the defect and the positional information on the defect.

Hereinafter, details of a defect inspection method by the semiconductor inspection apparatus 101 illustrated in FIG. 4 will be described. In the second inspection process (step S7), inspection by the PL method is executed. The dislocation plane of the defect formed in the semiconductor crystal does not necessarily reach the surface of the epitaxial layer. However, the defect may be expanded due to the influence of charge energy supplied along with energization to the semiconductor chip. The inspection by the PL method is important from the viewpoint of capturing defects involved in the lifetime of the semiconductor device because it is possible to observe the expansion of defects occurring in the epitaxial layer.

However, in the PL image, some of basal plane dislocations (BPD) and stacking faults (SF) may be detected as linear defects. In that case, it is difficult to distinguish between the BPD and the SF on the basis of the PL image. Therefore, the first inspection process (step S4) is executed in addition to the second inspection process (step S7). The first inspection is an inspection using a differential interference optical system sensitive to unevenness of the surface of the semiconductor wafer. According to the surface image acquired by the differential interference optical system, the BPD in which unevenness does not appear on the surface of the semiconductor wafer and the SF in which unevenness appears can be distinguished and detected.

The first inspection process (step S4) is performed after the photolithography process (step S3) and before the ion implantation process (step S5). If the first inspection process is executed after the ion implantation process (step S5), a contrast of luminance corresponding to the mask pattern at the time of ion implantation is generated in the surface image. The contrast makes it difficult to detect the defect. Therefore, the first inspection process is executed before the ion implantation process (step S5). In addition, since the timing of the second inspection is different from the timing of the first inspection, it is necessary to correct the positional relationship between the PL image and the surface image at the time of collation. The semiconductor inspection apparatus 101 according to the first preferred embodiment corrects offset values in two axis (X axis and Y axis) directions and a rotation direction of each image based on the mark formed in the photolithography process (step S3). Therefore, the first inspection process is performed after the photolithography process (step S3).

In the wafer test process (step S9), a semiconductor chip whose test result is out of specification is removed and discarded. The processing subsequent to step S9 is not executed on the semiconductor chip that is out of specification. However, even in the semiconductor chip determined as a non-defective product in the wafer test process (step S9), the semiconductor chip may include a defect that gradually degrades the characteristics of the semiconductor device by the drive current. It is difficult to exclude the semiconductor chip including such a defect in the wafer test process (step S9). Therefore, the screening process (step S10) is executed.

Hereinafter, details of the screening process illustrated in FIG. 5 will be described. In an image analysis step (step S103), the image analysis unit 31 executes image processing of reducing the contrast of the luminance based on the mask pattern at the time of ion implantation superimposed on the PL image. In a case where the contrast variation has a longer period than the defect size, the image analysis unit 31 performs subtraction processing according to the period. Alternatively, the image analysis unit 31 may designate a contrast value for each pattern area on the basis of the data of the chip pattern and execute the subtraction processing. The method of the subtraction processing is not limited.

In the defect coordinate collation step (step S104), the defect coordinate collation unit 32 scans the entire surfaces of the surface image and the PL image subjected to subtraction of the contrast, and acquires the luminance variation coordinates in the respective images. At this time, the defect coordinate collation unit 32 corrects the two axis (X axis and Y axis) directions and the rotation direction based on the mark formed at the time of photolithography, and collates the surface image with the PL image. In a case where the luminance variation coordinates in the respective images can be regarded as the same, the defect coordinate collation unit 32 determines that a defect exists at the position. Then, the defect coordinate collation unit 32 extracts a partial image including the defect.

In the defect classification step (step S105), the defect classifier 33 acquires data of a partial image of the defect in the surface image and data of a partial image of the defect in the PL image. The defect classifier 33 identifies the type of the defect based on the partial images of the defects. For example, the defect classifier 33 identifies the type of the defect using the defect located in the entire region of the semiconductor chip as the classification target on the basis of the information on the position of the defect.

In a determination process (step S106), the quality determiner 34 determines whether or not a type of defect that affects the reliability is included in the semiconductor chip on the basis of the information on the type of the defect and the positional information on the defect. When a type of defect that affects the reliability is included, the quality determiner 34 labels the semiconductor chip including the defect as a defective product. When a type of defect that affects the reliability is not included, the quality determiner 34 labels the semiconductor chip as a non-defective product.

The semiconductor inspection apparatus 101 performs similar processing on all defects detected on the entire surface of the semiconductor wafer. The semiconductor inspection apparatus 101 removes the defective product based on the label of each semiconductor chip at the time when the processing is completed.

To summarize the above, the semiconductor inspection apparatus 101 according to the first preferred embodiment includes the first inspection information acquisition unit 10, the second inspection information acquisition unit 20, and the screening unit 30. The first inspection information acquisition unit 10 acquires first image information including unevenness information on the surface of the semiconductor wafer before ion implantation. The second inspection information acquisition unit 20 acquires second image information including information on photoluminescence in the semiconductor wafer subjected to heat treatment after the ion implantation. The screening unit 30 specifies a defect included in the semiconductor wafer on the basis of the first image information and the second image information, and determines the quality of a semiconductor chip formed on the semiconductor wafer.

Such a semiconductor inspection apparatus 101 improves the classification accuracy in defect inspection, and determines the quality of the semiconductor chip with high accuracy. Even when expansion or contraction of the defect occurs due to the energy during the heat treatment, the semiconductor inspection apparatus 101 determines the quality of the semiconductor chip based on the inspection result reflecting the state of the semiconductor crystal. The classification accuracy of the types of defects is improved, for example, the accuracy of detecting a BPD that is difficult to identify is improved in a single inspection process. Since the semiconductor inspection apparatus 101 screens semiconductor chips that may deteriorate in the future with high accuracy, the ratio of defective products introduced to the market is reduced. In addition, since the second inspection is executed after the heat treatment at 1000° C. or higher, it is possible to perform the quality determination in the crystalline state close to the state of the completed product, and the determination accuracy is improved. Furthermore, since the contrast reduction processing is performed on the PL image, the reflection of the mask pattern is removed.

The defect extraction accuracy is improved, and the defect classification accuracy is also improved.

### Modification of First Preferred Embodiment

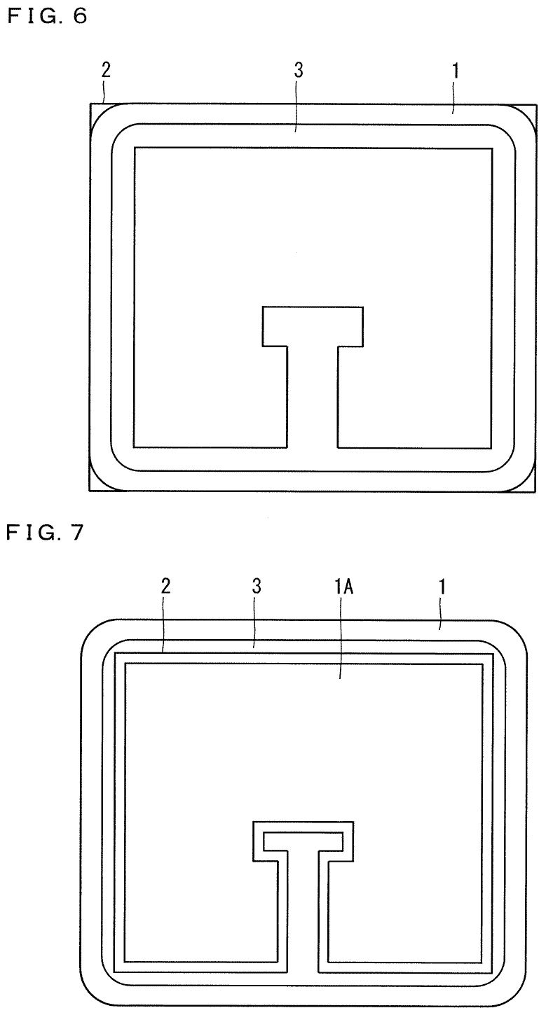

FIGS. 6 and 7 are diagrams illustrating the configuration of a semiconductor chip 1 and a defect inspection region 2. In FIG. 6, the entire region of the semiconductor chip 1 is included in the defect inspection region 2. In FIG. 7, only an effective region 1A in the semiconductor chip 1 is included in the defect inspection region 2. The effective region 1A corresponds to, for example, a region inside a gate electrode 3 provided along the outer periphery of the semiconductor chip 1.

As illustrated in FIG. 6, the defect classifier 33 may identify the type of the defect by using the defect located in the entire region of the semiconductor chip 1 as the classification target. However, when the semiconductor device is driven, a current flows only in the effective region 1A of the semiconductor chip 1. In a case where a defect to be excluded is included outside the effective region 1A, the semiconductor chip 1 that can originally be shipped as a non-defective product is discarded, and the yield decreases. Therefore, as illustrated in FIG. 7, the defect classifier 33 may identify the type of the defect by using the defect located only in the effective region 1A as the classification target on the basis of the information on the position of the defect and the information on the effective region 1A of the semiconductor chip 1. The efficiency of the quality determination of the semiconductor chip 1 is improved, and the determination accuracy is also improved.

Furthermore, the yield is improved.

### Second Preferred Embodiment

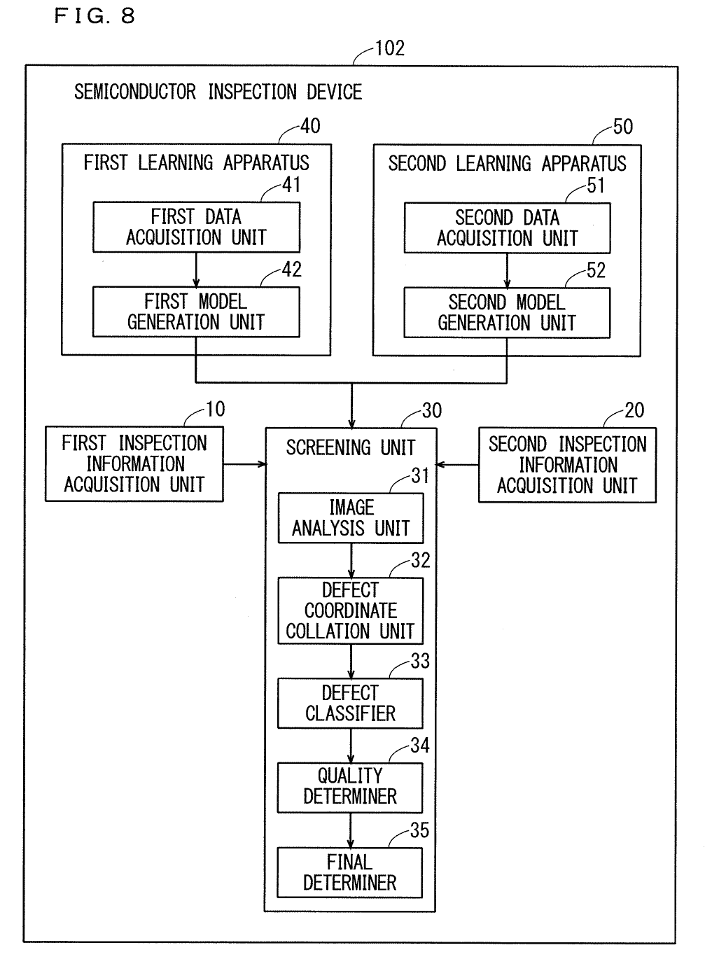

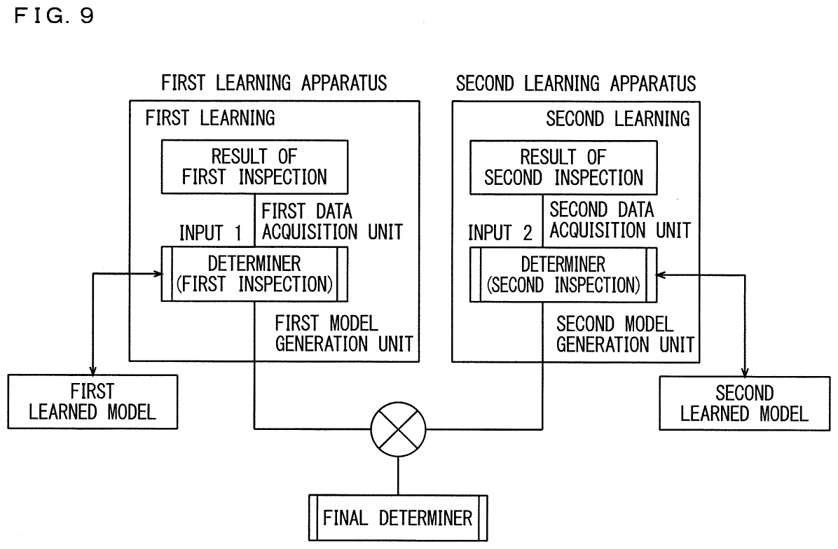

FIG. 8 is a diagram illustrating a configuration of a semiconductor inspection apparatus 102 according to a second preferred embodiment. FIG. 9 is a diagram illustrating data processing in the semiconductor inspection apparatus 102. A defect classifier 33 and a quality determiner 34 of the semiconductor inspection apparatus 102 preferably include a learned model learned by machine learning from the viewpoint of throughput of automatic classification and automatic determination.

The semiconductor inspection apparatus 102 includes a first learning apparatus 40 and a second learning apparatus 50. The first learning apparatus 40 includes a first data acquisition unit 41 and a first model generation unit 42. The second learning apparatus 50 includes a second data acquisition unit 51 and a second model generation unit 52. A screening unit 30 of the semiconductor inspection apparatus 102 includes a final determiner 35 in addition to the configuration of the first preferred embodiment.

The first data acquisition unit 41 acquires first learning data based on the first image information and the defect classification result. The first image information in the second preferred embodiment is a learning surface image captured by the differential interference optical system. The first learning data includes data in which a partial image of the defect in the learning surface image and the classification result of the type of the defect are associated with each other. As the classification result of the type of the defect, for example, a result of classification by visual observation by the worker is used.

The first model generation unit 42 performs learning using the first learning data, and generates a first learned model for inferring the type of a defect included in a surface image of a semiconductor wafer.

The defect classifier 33 identifies the type of the defect included in the surface image on the basis of the surface image acquired from the first inspection information acquisition unit 10 as a result of the first inspection process and the first learned model.

The quality determiner 34 determines whether or not a type of defect that affects the reliability is included in the semiconductor chip 1 on the basis of the information on the type of the defect and the positional information on the defect. When a type of defect that affects the reliability is included, the quality determiner 34 labels the semiconductor chip 1 that a defect that affects the reliability is included. When a type of defect that affects the reliability is not included, the quality determiner 34 labels the semiconductor chip 1 as a non-defective product.

The second data acquisition unit 51 acquires second learning data based on the second image information and the defect classification result. The second image information in the second preferred embodiment is a learning PL image measured by the PL method. The second learning data includes data in which a partial image of the defect in the learning PL image and the classification result of the type of the defect are associated with each other. As the classification result of the type of the defect, for example, a result of classification by visual observation by the worker is used.

The second model generation unit 52 performs learning using the second learning data, and generates a second learned model for inferring the type of the defect included in the PL image of the semiconductor wafer.

The defect classifier 33 identifies the type of the defect included in the PL image on the basis of the PL image acquired from the second inspection information acquisition unit 20 as a result of the second inspection process and the second learned model.

The quality determiner 34 determines whether or not a type of defect that affects the reliability is included in the semiconductor chip 1 on the basis of the information on the type of the defect and the positional information on the defect. When a type of defect that affects the reliability is included, the quality determiner 34 labels the semiconductor chip 1 that a defect that affects the reliability is included. When a type of defect that affects the reliability is not included, the quality determiner 34 labels the semiconductor chip 1 as a non-defective product.

The final determiner 35 acquires information on the label of the defect classified on the basis of the first learned model, and information on the label of the defect classified on the basis of the second learned model. The final determiner 35 determines the quality of the semiconductor chip 1 based on the information on the label and a predetermined rule. For example, in a case where at least one defect having a high probability of reaching element destruction is included, the final determiner 35 determines that the semiconductor chip 1 is a defective product. Alternatively, although it cannot be said that the probability of element destruction of the semiconductor chip 1 is high, in a case where three or more defects affecting the characteristics are included, the final determiner 35 determines that the semiconductor chip 1 is a defective product.

As described above, the screening unit 30 determines the quality of the semiconductor chip 1 on the basis of the first image information acquired from the first inspection information acquisition unit 10, the second image information acquired from the second inspection information acquisition unit 20, the first learned model, and the second learned model.

According to such a configuration, not only the determination criterion is stabilized as compared with the classification by the visual determination by the worker, but also the determination accuracy in the automatic processing is improved, and the throughput is improved.

The functions of the first learning apparatus 40, the second learning apparatus 50, and the final determiner 35 are implemented by the processing circuit illustrated in FIG. 2 or 3. Each of the first learning apparatus 40, the second learning apparatus 50, and the semiconductor inspection apparatus 102 may have its own processing circuit. For example, the first learning apparatus 40 and the second learning apparatus 50 may be provided in the server.

### Modification of Second Preferred Embodiment

A learned model obtained by machine learning may be applied to a predetermined rule used by the final determiner 35.

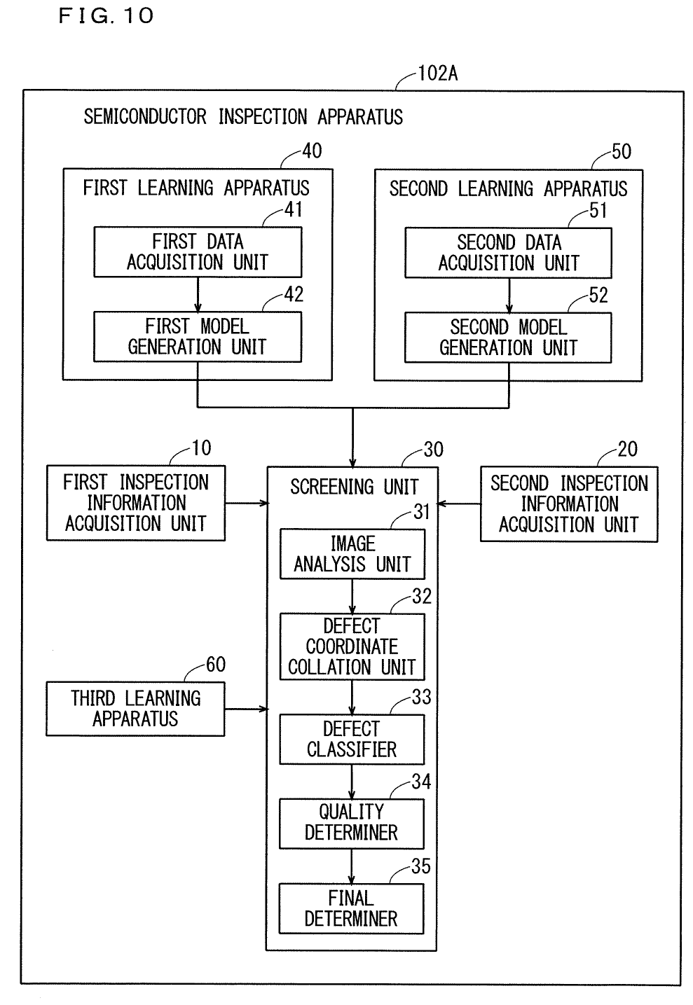

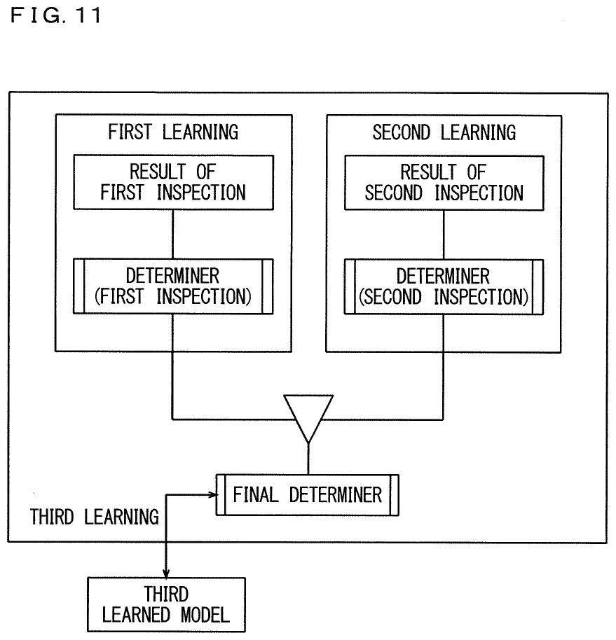

FIG. 10 is a diagram illustrating a configuration of a semiconductor inspection apparatus 102A according to a modification of the second preferred embodiment. FIG. 11 is a diagram illustrating data processing in the semiconductor inspection apparatus 102A.

The semiconductor inspection apparatus 102A includes a third learning apparatus 60. The third learning apparatus 60 performs ensemble learning based on the information on the type of the defect identified based on the first learned model, the information on the type of the defect identified based on the second learned model, and the degradation data of the electrical characteristics of the semiconductor chip 1. The third learning apparatus 60 generates a third learned model for inferring the quality of the semiconductor chip 1 by the ensemble learning. The deterioration data of the electrical characteristics of the semiconductor chip 1 corresponds to, for example, a label for which determination of a non-defective product and a defective product is made based on the deterioration state of the electrical characteristics after the energization load test that simulates operation in the market. In the learning step, the defect type information and the label are associated with each other.

The final determiner 35 finally determines the quality of the semiconductor chip 1 based on the third learned model.

The function of the third learning apparatus 60 is realized by the processing circuit illustrated in FIG. 2 or 3. The third learning apparatus 60 may have a unique processing circuit. For example, the third learning apparatus 60 may be provided in the server.

According to such a configuration, as the production number of the semiconductor chips 1 increases, a lot of learning data is provided, so that a determination result with higher accuracy can be obtained. In the present modification, ensemble learning close to stacking is adopted. In order to utilize bagging, boosting, and the like, ensemble learning may also be applied to each unit of each learning apparatus. Although the time and cost required for learning and inference are increased, the determination accuracy is improved.

### Third Preferred Embodiment

The semiconductor inspection apparatus 102 according to the second preferred embodiment generates a learned model by independently learning the defect images extracted in the first inspection and the second inspection by the first learning apparatus 40 and the second learning apparatus 50. In the machine learning of the second preferred embodiment, only the luminance information is referred to without referring to the color information on the defect image (the PL image does not originally have the color information). In a case where a composite image having multiple channels is used as an input in machine learning, the number of times of learning and inference is reduced.

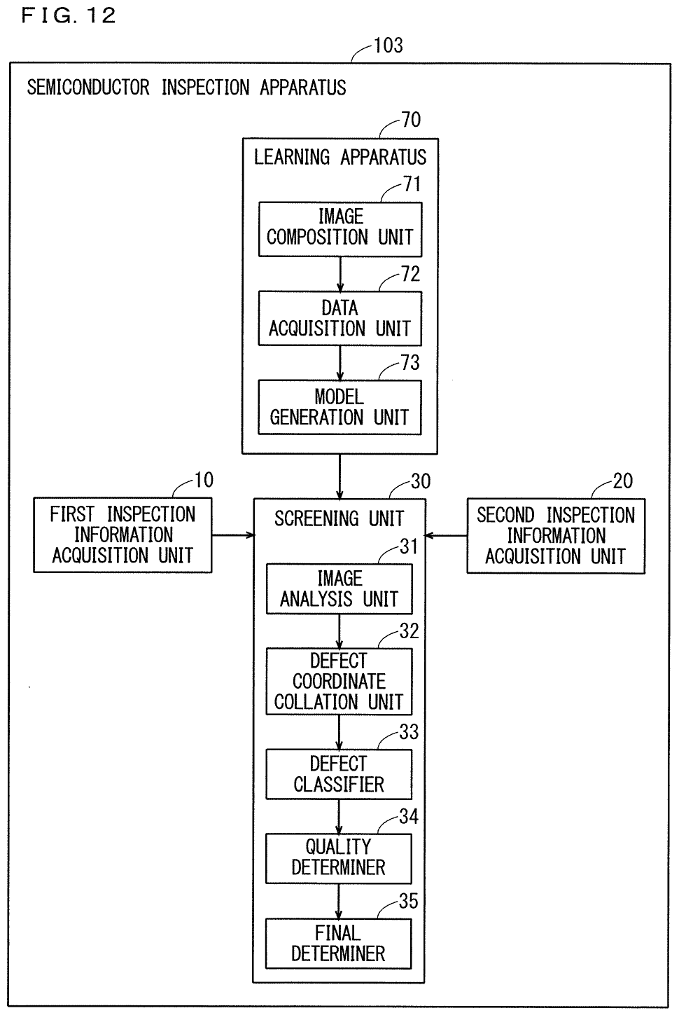

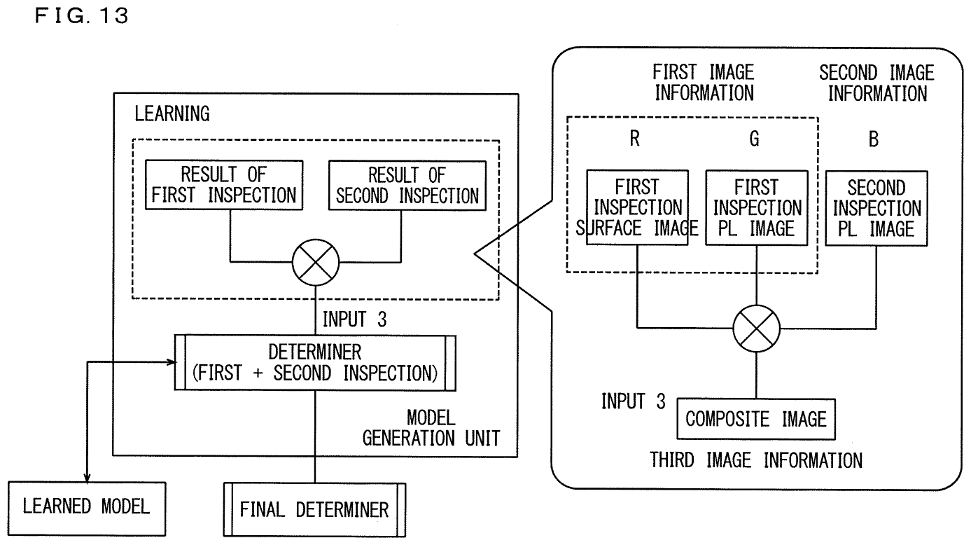

FIG. 12 is a diagram illustrating a configuration of a semiconductor inspection apparatus 103 according to the third preferred embodiment. FIG. 13 is a diagram illustrating data processing in the semiconductor inspection apparatus 103.

The semiconductor inspection apparatus 103 includes a learning apparatus 70. The learning apparatus 70 includes an image composition unit 71, a data acquisition unit 72, and a model generation unit 73. The screening unit 30 includes a final determiner 35 in addition to the configuration of the first preferred embodiment.

The image composition unit 71 generates third image information based on the first image information and the second image information. The third image information is a composite image obtained by combining the first image information and the second image information stored in different channels. In other words, the composite image is an image having multi-channels, and here, is a color image having three channels of RGB.

The image composition unit 71 generates a composite image on the basis of the surface image and the PL image. For example, the image composition unit 71 generates a composite image by allocating the surface image in the first inspection to the R channel, the PL image in the first inspection to the G channel, and the PL image in the second inspection to the B channel, among the RGB channels. As a result, the defect is regarded as a color image.

The data acquisition unit 72 acquires learning data based on the composite image and the defect classification result. The learning data includes, for example, data in which a partial image of a defect in the composite image and a classification result of the defect type are associated with each other. As the classification result of the type of the defect, for example, a result of classification by visual observation by the worker is used.

The model generation unit 73 performs learning using the learning data, and generates a learned model for inferring the type of the defect included in the composite image.

The defect classifier 33 identifies the type of the defect based on the learned model. Then, the quality determiner 34 determines whether or not a type of defect that affects the reliability is included in the semiconductor chip 1 on the basis of the information on the type of the defect and the positional information on the defect. When a type of defect that affects the reliability is included, the quality determiner 34 labels the semiconductor chip 1 that a defect that affects the reliability is included. When a type of defect that affects the reliability is not included, the quality determiner 34 labels the semiconductor chip 1 as a non-defective product. The final determiner 35 determines the quality of the semiconductor chip 1 based on the information on the label of the defect. In this manner, the screening unit 30 determines the quality of the semiconductor chip 1 on the basis of the learned model.

Each function of the learning apparatus 70 and the final determiner 35 is realized by the processing circuit illustrated in FIG. 2 or 3. Each of the learning apparatus 70 and the semiconductor inspection apparatus 103 may have its own processing circuit. For example, the learning apparatus 70 may be provided in the server.

With such a configuration, the number of determinations by the quality determiner 34 is reduced. The load of model management is reduced, and the time required for learning and inference is shortened. In addition, since the comparison between the surface image in the first inspection and the PL image in the second inspection is reflected in the machine learning, the determination accuracy is improved.

Note that the preferred embodiments can be freely combined, and the preferred embodiments can be appropriately modified or omitted.

Hereinafter, various aspects of the present disclosure will be collectively described as appendixes.

### APPENDIX 1

A semiconductor inspection apparatus comprising:
a first inspection information acquisition unit that acquires first image information including irregularity information on a surface of a semiconductor wafer before ion implantation;
a second inspection information acquisition unit that acquires second image information including information on photoluminescence in the semiconductor wafer subjected to heat treatment after the ion implantation; and
a screening unit that specifies a defect included in the semiconductor wafer on the basis of the first image information and the second image information, and determines quality of a semiconductor chip formed on the semiconductor wafer.

### APPENDIX 2

The semiconductor inspection apparatus according to appendix 1, wherein the second image information includes information on the photoluminescence in the semiconductor wafer subjected to the heat treatment at a temperature of 1000° C. or higher.

### APPENDIX 3

The semiconductor inspection apparatus according to appendix 1 or 2, wherein
the screening unit includes:
   an image analysis unit that performs subtraction of contrast related to an ion implantation pattern of the semiconductor wafer in the second image information;
   a defect classifier that identifies a type of the defect on the basis of the first image information and the second image information subjected to the subtraction of the contrast; and
a determiner that determines the quality of the semiconductor chip on the basis of information on the type of the defect.

### APPENDIX 4

The semiconductor inspection apparatus according to appendix 3, wherein
the screening unit further includes a defect coordinate collation unit that specifies a position of the defect included in the semiconductor wafer on the basis of the first image information and the second image information, and
the defect classifier identifies the type of the defect by using the defect located in an entire region of the semiconductor chip or the defect located only in an effective region provided in the semiconductor chip as a classification target, on the basis of the information on the position of the defect.

### APPENDIX 5

The semiconductor inspection apparatus according to any one of appendixes 1 to 4, further comprising a first learning apparatus and a second learning apparatus, wherein
the first learning apparatus includes:
   a first data acquisition unit that acquires first learning data based on the first image information and a classification result of the defect; and
   a first model generation unit that generates a first learned model for inferring a type of the defect included in the first image information by using the first learning data,
the second learning apparatus includes:
   a second data acquisition unit that acquires second learning data based on the second image information and a classification result of the defect; and
   a second model generation unit that generates a second learned model for inferring the type of the defect included in the second image information by using the second learning data, and
the screening unit determines the quality of the semiconductor chip on the basis of the first image information acquired from the first inspection information acquisition unit, the second image information acquired from the second inspection information acquisition unit, the first learned model, and the second learned model.

### APPENDIX 6

The semiconductor inspection apparatus according to appendix 5, further comprising a third learning apparatus, wherein
the third learning apparatus generates a third learned model for inferring the quality of the semiconductor chip by ensemble learning based on information on the type of the defect identified on the basis of the first learned model, information on the type of the defect identified on the basis of the second learned model, and degradation data of electrical characteristics of the semiconductor chip, and
the screening unit determines the quality of the semiconductor chip on the basis of the third learned model.

### APPENDIX 7

The semiconductor inspection apparatus according to any one of appendixes 1 to 6, further comprising a learning apparatus, wherein
the learning apparatus includes:
   an image composition unit that generates third image information composed by storing the first image information and the second image information in different channels;
   a data acquisition unit that acquires learning data based on the third image information and a classification result of the defect; and
   a model generation unit that generates a learned model for inferring a type of the defect included in the third image information by using the learning data, and
the screening unit determines the quality of the semiconductor chip on the basis of the learned model.

### APPENDIX 8

A method of manufacturing a semiconductor device, the method comprising:
acquiring first image information including irregularity information on a surface of a semiconductor wafer before ion implantation;
acquiring second image information including information on photoluminescence in the semiconductor wafer subjected to heat treatment after the ion implantation; and
extracting a defect included in the semiconductor wafer on the basis of the first image information and the second image information, and determining quality of a semiconductor chip formed on the semiconductor wafer.

### APPENDIX 9

The method of manufacturing the semiconductor device according to appendix 8, further comprising:
a first inspection process of photographing a surface image of the semiconductor wafer;
an ion implantation process of implanting ions into the semiconductor wafer after the first inspection process;
a heat treatment process of heat-treating the semiconductor wafer after the ion implantation process; and
a second inspection process of measuring a photoluminescence image of the semiconductor wafer after the heat treatment process,
wherein the first image information is the surface image photographed in the first inspection process, and
the second image information is the photoluminescence image measured in the second inspection process.

While the disclosure has been shown and described in detail, the foregoing description is in all aspects illustrative and not restrictive. It is therefore understood that numerous modifications and variations can be devised.

What is claimed is:

1. A semiconductor inspection apparatus comprising:
first inspection information acquisition circuitry that acquires first image information including irregularity information on a surface of a semiconductor wafer before ion implantation;
second inspection information acquisition circuitry that acquires second image information including information on photoluminescence in the semiconductor wafer subjected to heat treatment after the ion implantation; and
screening circuitry that specifies a defect included in the semiconductor wafer on the basis of the first image information and the second image information, and determines quality of a semiconductor chip formed on the semiconductor wafer.

2. The semiconductor inspection apparatus according to claim 1, wherein the second image information includes information on the photoluminescence in the semiconductor wafer subjected to the heat treatment at a temperature of 1000° C. or higher.

3. The semiconductor inspection apparatus according to claim 1, wherein
the screening circuitry includes:
image analysis circuitry that performs subtraction of contrast related to an ion implantation pattern of the semiconductor wafer in the second image information;
a defect classifier that identifies a type of the defect on the basis of the first image information and the second image information subjected to the subtraction of the contrast; and
a determiner that determines the quality of the semiconductor chip on the basis of information on the type of the defect.

4. The semiconductor inspection apparatus according to claim 3, wherein
the screening circuitry further includes defect coordinate collation circuitry that specifies a position of the defect included in the semiconductor wafer on the basis of the first image information and the second image information, and
the defect classifier identifies the type of the defect by using the defect located in an entire region of the semiconductor chip or the defect located only in an effective region provided in the semiconductor chip as a classification target, on the basis of the information on the position of the defect.

5. The semiconductor inspection apparatus according to claim 1, further comprising a first learning apparatus and a second learning apparatus, wherein
the first learning apparatus includes:
first data acquisition circuitry that acquires first learning data based on the first image information and a classification result of the defect; and
first model generation circuitry that generates a first learned model for inferring a type of the defect included in the first image information by using the first learning data,
the second learning apparatus includes:
second data acquisition circuitry that acquires second learning data based on the second image information and a classification result of the defect; and
second model generation circuitry that generates a second learned model for inferring the type of the defect included in the second image information by using the second learning data, and
the screening circuitry determines the quality of the semiconductor chip on the basis of the first image information acquired from the first inspection information acquisition circuitry, the second image information acquired from the second inspection information acquisition circuitry, the first learned model, and the second learned model.

6. The semiconductor inspection apparatus according to claim 5, further comprising a third learning apparatus, wherein
the third learning apparatus generates a third learned model for inferring the quality of the semiconductor chip by ensemble learning based on information on the type of the defect identified on the basis of the first learned model, information on the type of the defect identified on the basis of the second learned model, and degradation data of electrical characteristics of the semiconductor chip, and
the screening circuitry determines the quality of the semiconductor chip on the basis of the third learned model.

7. The semiconductor inspection apparatus according to claim 1, further comprising a learning apparatus, wherein
the learning apparatus includes:
image composition circuitry that generates third image information composed by storing the first image information and the second image information in different channels;
data acquisition circuitry that acquires learning data based on the third image information and a classification result of the defect; and
model generation circuitry that generates a learned model for inferring a type of the defect included in the third image information by using the learning data, and
the screening circuitry determines the quality of the semiconductor chip on the basis of the learned model.

8. A method of manufacturing a semiconductor device, the method comprising:
acquiring first image information including irregularity information on a surface of a semiconductor wafer before ion implantation;
acquiring second image information including information on photoluminescence in the semiconductor wafer subjected to heat treatment after the ion implantation; and
extracting a defect included in the semiconductor wafer on the basis of the first image information and the second image information, and determining quality of a semiconductor chip formed on the semiconductor wafer.

9. The method of manufacturing the semiconductor device according to claim 8, further comprising:
a first inspection process of photographing a surface image of the semiconductor wafer;
an ion implantation process of implanting ions into the semiconductor wafer after the first inspection process;
a heat treatment process of heat-treating the semiconductor wafer after the ion implantation process; and
a second inspection process of measuring a photoluminescence image of the semiconductor wafer after the heat treatment process,
wherein he first image information is the surface image photographed in the first inspection process, and
the second image information is the photoluminescence image measured in the second inspection process.
